(19) United States
(12) Patent Application Publication
(10) Pub. No.: US 2013/0308403 A1
(43) Pub. Date: Nov. 21, 2013

(54) SEMICONDUCTOR DEVICE HAVING SENSE AMPLIFIER CIRCUIT

(71) Applicant: Elpida Memory, Inc., Tokyo (JP)

(72) Inventors: Izumi NAKAI, Tokyo (JP); Takeshi OHGAMI, Tokyo (JP); Noriaki MOCHIDA, Tokyo (JP); Yasuhiro MATSUMOTO, Tokyo (JP)

(73) Assignee: Elpida Memory, Inc., Tokyo (JP)

(21) Appl. No.: 13/895,195

(22) Filed: May 15, 2013

(30) Foreign Application Priority Data
May 15, 2012 (JP) 2012-111809

(51) Int. Cl. G11C 7/12; G11C 7/06

(52) U.S. Cl. CPC G11C 7/12; G11C 7/06
USPC 365/203

(57) ABSTRACT

Disclosed herein is a device that includes: a first control element that controls an amount of current flowing between a second line and a first node according to a potential of a first line; a second control element that controls an amount of current flowing between the first line and the first node according to a potential of the second line; a first control circuit that performs a first operation to fix potentials of the first and second lines at a first potential; a second control circuit that performs a second operation to connect the first node to the second node; and a third control circuit that fixes a potential of the first node at a second potential after the first control circuit stops the first operation until the second control circuit starts the second operation.

### BACKGROUND OF THE INVENTION

1. Field of the Invention

The present invention relates to a semiconductor device, and more particularly relates to a semiconductor device including sense amplifiers each of which amplifies a potential difference occurring in a pair of bit lines.

2. Description of Related Art

Many of semiconductor memory devices represented by a DRAM (Dynamic Random Access Memory) include sense amplifiers each of which amplifies a potential difference occurring in a pair of bit lines. For example, a DRAM described in Japanese Patent Application Laid-open No. 2011-187879 has sense amplifiers each including two p-channel MOS transistors cross-coupled and two n-channel MOS transistors cross-coupled, and drives one bit line of a bit line pair to an array potential (VARY) and the other bit line of the bit line pair to a ground potential (VSS) based on a potential difference occurring in the bit line pair.

In Japanese Patent Application Laid-open No. 2011-187879, a sequence of a read operation using the sense amplifiers (SA) is performed as follows. At a time before performing the read operation, a bit-line equalization signal (BLEQ) is first activated, which causes a bit line pair to be precharged with a bit-line precharge voltage (VBLP) by a bit-line precharge circuit (PCC). When the read operation is started, the bit-line equalization signal is deactivated and supply of the bit-line precharge voltage by the bit-line precharge circuit is stopped. Accordingly, the bit line pair is brought into a floating state while being kept at the same potential. A specific word line is selected in this state. Transfer of charges between a cell capacitor of a selected memory cell and a bit line changes the potential of the bit line, resulting in a potential difference in the bit line pair. Sense-amplifier enable signals (SAPE and SANE) are then activated and thus a cross-coupled amplifier (CCA) included in the corresponding sense amplifier performs a sense operation to amplify the potential difference in the bit line pair and holds the amplified potential difference. A row-select switch signal (YS) is then activated to transfer the potential difference in the bit line pair to an IO line pair, or the like, and stored information is read.

As this reading method has been examined, the present inventors have found the following problem. That is, it was found that the potential difference in the bit line pair cannot be accurately read in some ways of controlling a common source potential of the cross-coupled amplifier in the sense amplifier. This problem occurs not only in the sense amplifier including the two cross-coupled p-channel MOS transistors and the two cross-coupled n-channel MOS transistors but also in a sense amplifier including only either two cross-coupled p-channel MOS transistors or two cross-coupled n-channel MOS transistors.

### SUMMARY

In one embodiment, there is provided a semiconductor device that includes: a first line; a second line; a first node; a second node supplied with a first power supply potential; a first control element that controls an amount of current flowing between the second line and the first node according to a potential of the first line; a second control element that controls an amount of current flowing between the first line and the first node according to a potential of the second line; a first control circuit that performs a first operation to fix potentials of the first and second lines at a first potential; a second control circuit that performs a second operation to connect the first node to the second node; and a third control circuit that fixes a potential of the first node at a second potential after the first control circuit stops the first operation until the second control circuit starts the second operation.

In another embodiment, there is provided a semiconductor device that includes: first and second bit lines; a sense amplifier driving one of the first and second bit lines to a potential supplied to a first common source node, and driving the other of the first and second bit lines to a potential supplied to a second common source node; a first precharge circuit that equalizes the first and second bit lines to substantially the same potential; a second precharge circuit that equalizes the first and second common source nodes to substantially the same potential; a first sense-amplifier drive circuit that drives the first common source node to a first activation potential; and a second sense-amplifier drive circuit that drives the second common source node to a second activation potential. The first and second sense-amplifier drive circuits and the first and second precharge circuits are activated mutually exclusively, and the second precharge circuit is deactivated after the first precharge circuit is deactivated.

In still another embodiment, there is provided a semiconductor device that includes: first and second bit lines; a first equalization circuit coupled to the first and second bit lines to equalize a potential between the first and second bit lines; a sense amplifier coupled the first and second bit lines; first and second source lines coupled to the sense amplifier to activate or deactivate the sense amplifier by a potential between the first and second source lines; a second equalization circuit coupled to the first and second source lines to equalize the potential between the first and second source lines; a first logic circuit configured to output a first control signal; a second logic circuit configured to receive the first control signal and output a second control signal applied to the first equalization circuit; and a third logic circuit configured to receive the first control signal and output a third control signal applied to the second equalization circuit, the third logic circuit being different from the second logic circuit.

In a semiconductor device according to the one embodiment of the present invention, a second control circuit that controls a potential of a common source node (first node) of a cross-coupled amplifier is controlled using a signal (second control signal) independent of a bit-line equalization signal (first control signal). Accordingly, a potential of a common source can be fixed independently of a bit-line equalization operation. For example, the common source node is not brought into a floating state also in a period after bit-line precharge is stopped until a sense amplifier is activated, so that changes in a bit line potential due to charge leakage can be reduced. Therefore, erroneous reading can be reduced.

### BRIEF DESCRIPTION OF THE DRAWINGS

FIG. 1 is a schematic diagram indicative of an overall structure of a semiconductor device and an enlarged view of a part of its structure according to a preferred embodiment of the present invention;

FIG. 2 is a circuit diagram indicative of a memory cell MC shown in FIG. 1;

FIG. 3 is a circuit diagram indicative of a circuit formed in each sense amplifier area SAA shown in FIG. 1;

FIG. 4 is a circuit diagram indicative of a sense amplifier SA and a bit-line precharge circuit BLPC shown in FIG. 3;

FIG. 5 is a circuit diagram of a circuit that controls potentials of common source lines PCS and NCS shown in FIGS. 3 and 4;

FIG. 6 is a circuit diagram of an equalization-signal generation circuit that the inventors have conceived as a prototype in the course of making the present invention;

FIG. 7 is an operation waveform chart of a semiconductor device that the inventors have conceived as a prototype in the course of making the present invention;

FIG. 8 is a waveform chart for explaining the sense amplifier SA erroneously operating;

FIG. 9A is a circuit diagram of an equalization-signal generation circuit according to a first embodiment of the present invention;

FIG. 9B is a circuit diagram of a circuit for generating a common-source equalization signal CSEQB shown in FIG. 9A;

FIG. 10 is an operation waveform chart of a semiconductor device according to the first embodiment;

FIG. 11 is a waveform chart of a potential change in each line according to the first embodiment;

FIG. 12 is an operation waveform chart of a semiconductor device according to a second embodiment of the present invention;

FIG. 13 is a schematic diagram for explaining a method wherein a timing signal SAN is used also as a common-source equalization signal CSEQB;

FIG. 14A is a circuit diagram of a sense amplifier including only p-channel MOS transistors;

FIG. 14B is a circuit diagram of a sense amplifier including only n-channel MOS transistors.

FIG. 15 is an example of an equalization-signal generation circuit according to the first embodiment of the present invention; and

FIG. 16 is an alternative operation waveform chart of the example of the equalization-signal generation circuit of FIG. 15.

### DETAILED DESCRIPTION OF THE EMBODIMENTS

Preferred embodiments of the present invention will be explained below in detail with reference to the accompanying drawings. The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessarily mutually exclusive, as some disclosed embodiments can be combined with one or more other disclosed embodiments to form new embodiments.

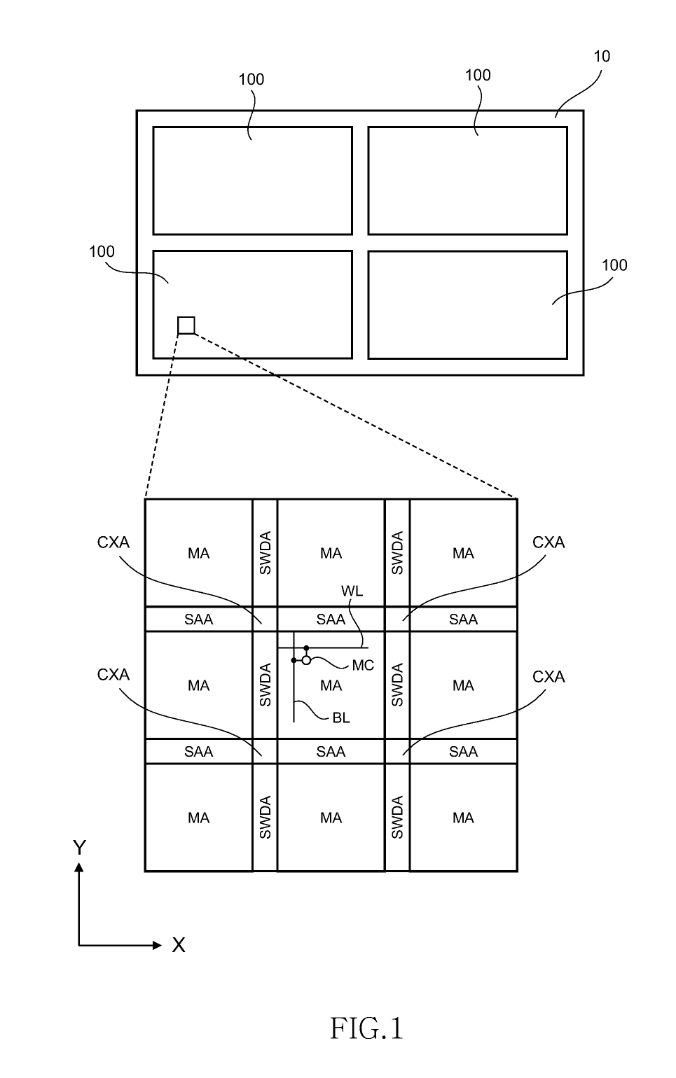

Referring now to FIG. 1, FIG. 1, the semiconductor device 10 according to the present embodiment includes a plurality of (four in the embodiment) memory cell arrays 100. Although external terminals such as an address terminal and a power supply terminal and various peripheral circuits such as an address decoder, a control logic circuit, a data input/output circuit, and the like are arranged outside of the memory cell arrays 100, they are not shown in FIG. 1.

As shown in the enlarged view of FIG. 1, each memory cell array 100 includes a plurality of memory mat areas MAs arranged in a matrix. Regions between the memory mat areas MAs adjacent in an X direction are used as sub-word areas SWDAs, and those between the memory mat areas MAs adjacent in a Y direction are used as sense amplifier areas SAAs. In the present embodiment, the X direction is an extension direction of word lines WLs and the Y direction is an extension direction of bit lines BLs.

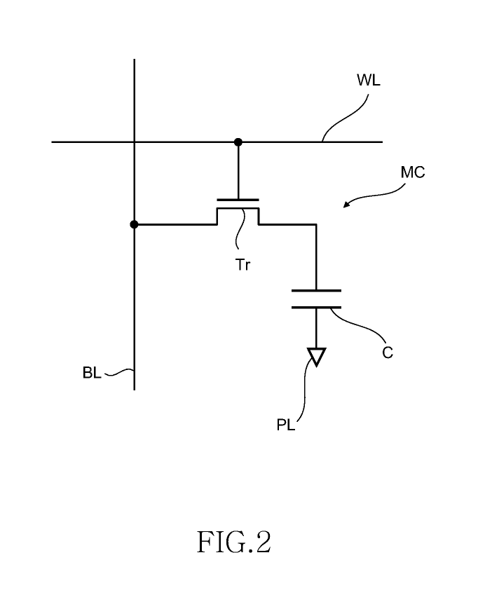

Many (e.g., 256K) memory cells MCs are arranged in each memory mat area MA. As shown in FIG. 2, each of the memory cells MCs is configured to include a cell transistor Tr and a cell capacitor C connected in series between each bit line BL and a plate line PL. A gate electrode of the cell transistor Tr is connected to each word line WL. By so configuring, when a word line WL becomes high level, the cell transistor Tr of the memory cell MC is turned on and the cell capacitor C thereof is connected to a corresponding bit line BL. While the cell capacitor C is used as a memory element because the semiconductor device according to the present embodiment is a DRAM, a memory element different from the cell capacitor C is used in a semiconductor memory device other than the DRAM.

When data is to be written in a memory cell MC, an array potential VARY or a ground potential VSS (<VARY) is supplied to the corresponding cell capacitor C according to the data to be stored. The ground potential VSS is an external potential supplied from outside the semiconductor device 10 and the array potential VARY is an internal potential generated inside the semiconductor device 10. When data is to be read from a memory cell MC, the corresponding bit line BL is precharged with a precharge potential VBLP and then the corresponding cell transistor Tr is turned on. The precharge potential VBLP is an intermediate potential between the array potential VARY and the ground potential VSS, that is, (VARY−VSS)/2. Accordingly, the potential of the bit line BL slightly increases from the precharge potential VBLP when the array potential VARY has been written in the cell capacitor C, and the potential of the bit line BL slightly decreases from the precharge potential VBLP when the ground potential VSS has been written in the cell capacitor C.

Driving of a word line WL is performed by a sub-word driver provided in the sub-word area SWDA and driving of a bit line BL is performed by a sense amplifier SA provided in the sense amplifier area SAA. The bit line BL is a general term used to refer to bit lines BLT and BLB explained later.

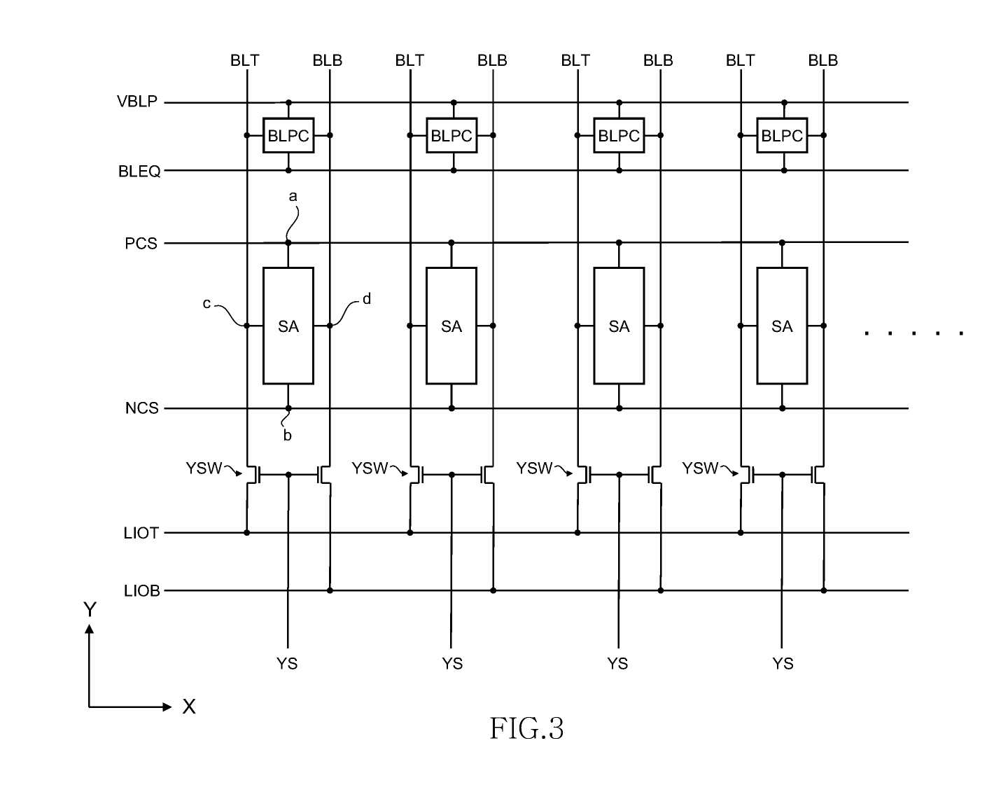

Turning to FIG. 3, the sense amplifier area SAA includes sense amplifiers SA, each of which is provided for each bit line pair BLT and BLB, a bit-line precharge circuit BLPC, and a column switch YSW. In the present invention, the bit-line precharge circuit BLPC is referred to also as “first control circuit”. Each of the sense amplifiers SA includes four nodes, i.e., a pair of common source nodes a and b and a pair of signal nodes c and d. The common source node a is connected to a high-potential common source line PCS and the common source node b is connected to a low-potential common source line NCS. Further, the signal nodes c and d are connected to corresponding bit line pair BLT and BLB, respectively. In the present invention, the bit lines BLT and BLB are referred to also as “first line” and “second line”, respectively.

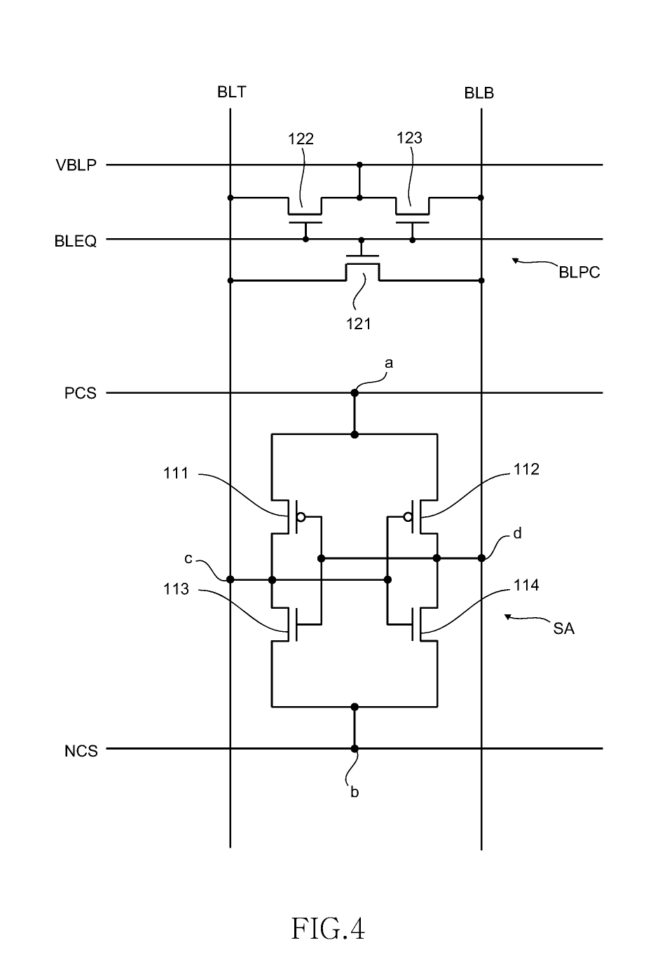

Turning to FIG. 4, the sense amplifier SA includes P-channel MOS transistors 111 and 112 and N-channel MOS transistors 113 and 114. The transistors 111 and 113 are connected in series between the common source nodes a and b. A contact node between the transistors 111 and 113 is connected to the signal node c, and gate electrodes of the transistors 111 and 113 are connected to the signal node d. Likewise, the transistors 112 and 114 are connected in series between the common source nodes a and b. A contact node between the transistors 112 and 114 is connected to the signal node d, and gate electrodes of the transistors 112 and 114 are connected to the signal node c.

Due to this flip-flop structure, if a potential difference is generated between the bit line pair BLT and BLB while a predetermined potential is supplied to the high-potential common source line PCS and the low-potential common source line NCS, then the potential of the high-potential common source line PCS is supplied to one of the bit line pair BLT and BLB, and that of the low-potential common source line NCS is supplied to the other of the bit line pair BLT and BLB. The active potential of the high-potential common source line PCS is an array potential VARY, and the active potential of the low-potential common source line NCS is a ground potential VSS.

An operation principle of the sense amplifier SA is as mentioned below. Regarding the p-channel MOS transistors 111 and 112, these transistors are cross-coupled and thus a difference in source-drain resistances between the two transistors 111 and 112 occurs when there is a slight difference between potentials of the gate electrodes, that is, potentials of the corresponding bit lines. Therefore, a transistor having a lower resistance transfers charges in a direction of causing the bit line and the common source line PCS to have the same potential faster than a transistor having a higher resistance. This transfer of charges further increases the potential difference in the bit line pair and enlarges the difference in source-drain resistances between the two transistors 111 and 112, and therefore the potential difference in the bit line pair is amplified. This operation is performed in the same manner also in the n-channel MOS transistors 113 and 114.

At a time before the sense operation mentioned above is performed, the bit line pair BLT and BLB is previously precharged with the precharge potential VBLP by the bit-line precharge circuit BLPC. When the precharge is thereafter stopped and then a word line WL corresponding to a memory cell MC that is connected to one of the bit lines BLT and BLB is selected to release charges only to the connected bit line BLT or BLB, a potential difference occurs between the bit lines BLT and BLB. With the sense operation mentioned above, the potential difference in the bit line pair BLT and BLB is amplified and kept.

The bit-line precharge circuit BLPC includes three n-channel MOS transistors 121 to 123. The transistor 121 is connected between the paired bit lines BLT and BLB, the transistor 122 is connected between the bit line BLT and a line to which the precharge potential VBLP is supplied, and the transistor 123 is connected between the bit line BLB and the line to which the precharge potential VBLP is supplied. A bit-line equalization signal BLEQ is supplied to all of gate electrodes of the transistors 121 to 123. With this configuration, when the bit-line equalization signal BLEQ is activated to a high level, the bit line pair BLT and BLB is precharged with the precharge potential VBLP.

Referring back to FIG. 3, the column switch YSW includes n-channel MOS transistors connected between the corresponding bit line pair BLT and BLB and a local-data line pair LIOT and LIOB. A corresponding column select line YS is supplied to each of the column switches YSW. Accordingly, when a predetermined column select line YS is activated to a high level, the corresponding bit line pair BLT and BLB is connected to the local-data line pair LIOT and LIOB. Therefore, read data amplified by the corresponding sense amplifier SA is transferred from the bit line pair BLT and BLB to the local-data line pair LIOT and LIOB at the time of a read operation, and write data is transferred from the local-data line pair LIOT and LIOB to the corresponding bit line pair BLT and BLB at the time of a write operation.

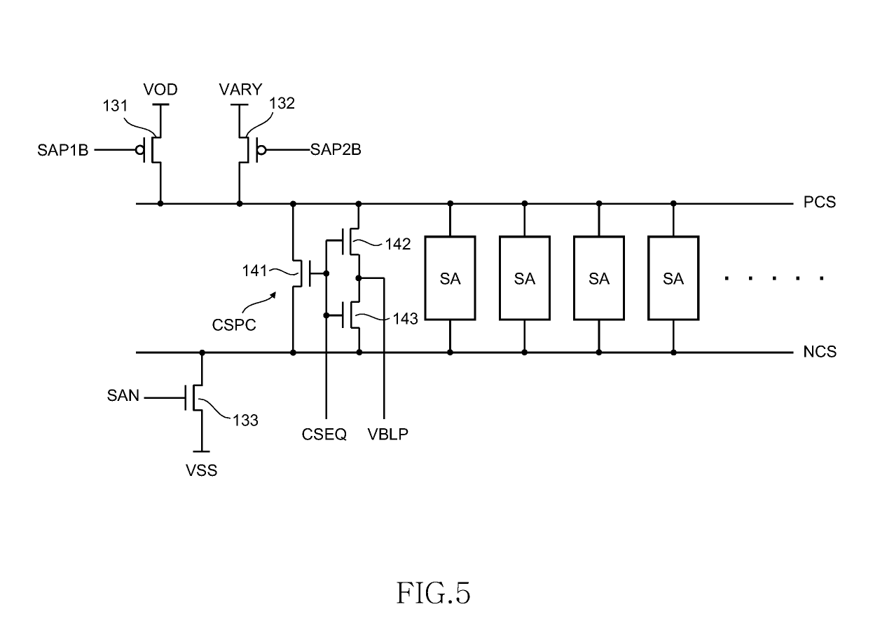

Turning to FIG. 5, p-channel MOS transistors 131 and 132 are connected to the high-potential common source line PCS. An overdrive potential VOD is supplied to a source of the transistor 131 and a timing signal SAP1B is supplied to a gate electrode thereof. The array potential VARY is supplied to a source of the transistor 132 and a timing signal SAP2B is supplied to a gate electrode thereof. Accordingly, the common source line PCS is driven to the overdrive potential VOD when the timing signal SAP1B is activated to a low level, and the common source line PCS is driven to the array potential VARY when the timing signal SAP2B is activated to a low level.

Meanwhile, an n-channel MOS transistor 133 is connected to the low-potential common source line NCS. The ground potential VSS is supplied to a source of the transistor 133 and a timing signal SAN is supplied to a gate electrode thereof. Accordingly, the common source line NCS is driven to the ground potential VSS when the timing signal SAN is activated to a high level. In the present invention, the common source line NCS and a line to which the ground potential VSS is supplied are referred to also as “first node” and “second node”, respectively. The transistor 133 is referred to also as “second control circuit”.

Furthermore, a common-source precharge circuit CSPC is connected between the common source lines PCS and NCS. The common-source precharge circuit CSPC has the same circuit configuration as that of the bit-line precharge circuit BLPC shown in FIG. 4 and includes three n-channel MOS transistors 141 to 143. The transistor 141 is connected between the common source lines PCS and NCS, the transistor 142 is connected between the common source line PCS and the line to which the precharge potential VBLP is supplied, and the transistor 143 is connected between the common source line NCS and the line to which the precharge potential VBLP is supplied. A common-source equalization signal CSEQ is supplied to all of gate electrodes of the transistors 141 to 143. With this configuration, when the common-source equalization signal CSEQ is activated to a high level, the common source lines PCS and NCS are precharged with the precharge potential VBLP. In the present invention, the common-source precharge circuit CSPC is referred to also as “third control circuit”.

A semiconductor device according to an example examined by the present inventors prior to the filing of the present application and problems thereof are explained below.

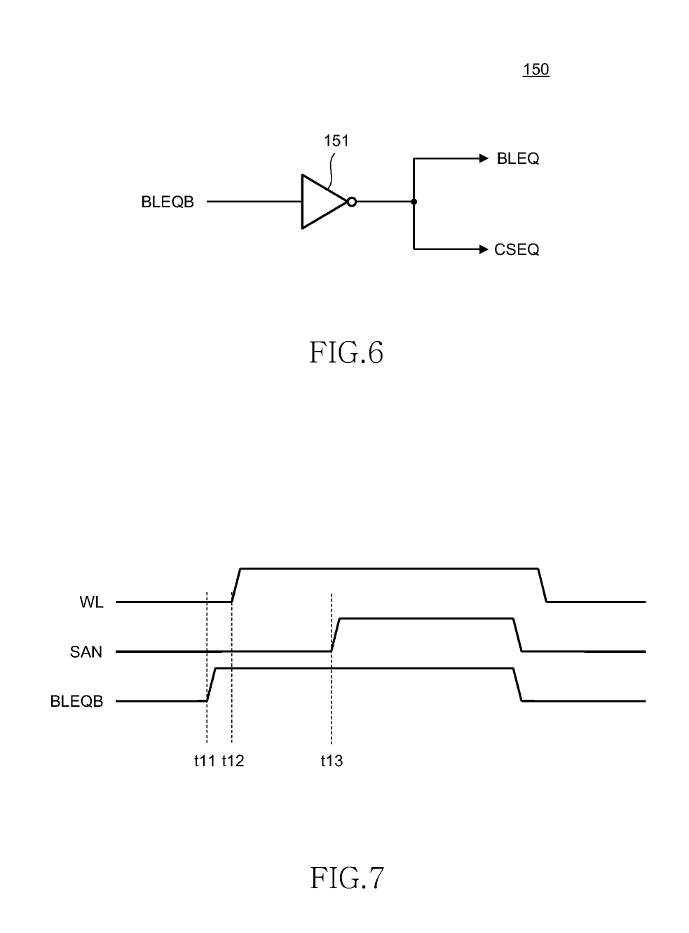

Turning to FIG. 6, the equalization-signal generation circuit 150 includes an inverter circuit 151 that receives a bit-line equalization signal BLEQB. An output of the inverter circuit 151 is used as the bit-line equalization signal BLEQ and the common-source equalization signal CSEQ. That is, in the present example, the bit-line equalization signal BLEQ and the common-source equalization signal CSEQ have the same waveform. Therefore, during a period in which the bit-line equalization signal BLEQB is activated to a low level, the bit line pair BLT and BLB and the common source lines PCS and NCS are all precharged with the precharge potential VBLP.

Turning to FIG. 7, the bit-line equalization signal BLEQB is activated to a low level in a period before a time t11. Accordingly, during this period, the bit-line precharge circuit BLPC and the common-source precharge circuit CSPC are both in an activated state and thus the bit line pair BLT and BLB and the common source lines PCS and NCS are all precharged with the precharge potential VBLP. The bit-line equalization signal BLEQB then changes to a high level at the time t11. This deactivates both of the bit-line precharge circuit BLPC and the common-source precharge circuit CSPC and the bit line pair BLT and BLB and the common source lines PCS and NCS are all brought into a floating state.

A predetermined word line WL is then activated to a high level at a time t12. This turns on the cell transistor Tr of the corresponding memory cell MC and connects the cell capacitor C thereof to the corresponding bit line BLT or BLB. As a result, the potential of the bit line BLT or BLB changes according to charges accumulated in the cell transistor Tr. This state is maintained for a while and, after the potential of the bit line BLT or BLB sufficiently changes, the timing signal SAN is activated to a high level at a time t13. Although not shown, the timing signal SAP1B is also activated to a low level at the time t13. This activates the sense amplifier SA to amplify a potential difference occurring in the bit line pair BLT and BLB. The timing signal SAP1B is activated only at an initial stage of the sense operation and the timing signal SAP2B is thereafter activated instead of the timing signal SAP1B to drive the common source line PCS to the array potential VARY.

The following problem occurs in the operation mentioned above. That is, because the common-source precharge circuit CSPC is deactivated during a period from the time t11 to the time t13, the common source lines PCS and NCS are in a floating state during this period. It is found that the following phenomenon may occur if a word line WL is selected and charges in the corresponding memory cell MC are released to one of the bit lines BLT and BLB in that state. For example, when High data is written in the memory cell MC, the potential of a bit line (BLT, for example) connected to the memory cell MC slightly increases. Generally, the increase in the potential of the bit line BLT is then kept and amplified upon start of the sense operation. However, if the potentials of the common source lines PCS and NCS are floating until the sense amplifier is operated as mentioned above, charges in the common source lines PCS and NCS are gradually lost due to off-leakage current of the transistors 111 to 114 included in the sense amplifier SA, or the like. If the charges in the common source lines PCS and NCS are lost, charges in the bit line pair BLT and BLB are also gradually lost.

In this case, because a source-drain potential difference between the transistors 111 and 113 having the drain electrodes connected to the bit line BLT with the slightly-increased potential is larger than that between the other transistors 112 and 114, charges are lost faster from the bit line BLT than from the bit line BLB. As a result, the potential difference in the bit line pair BLT and BLB becomes smaller and, in some cases, may be reversed and erroneously amplified by the sense amplifier SA.

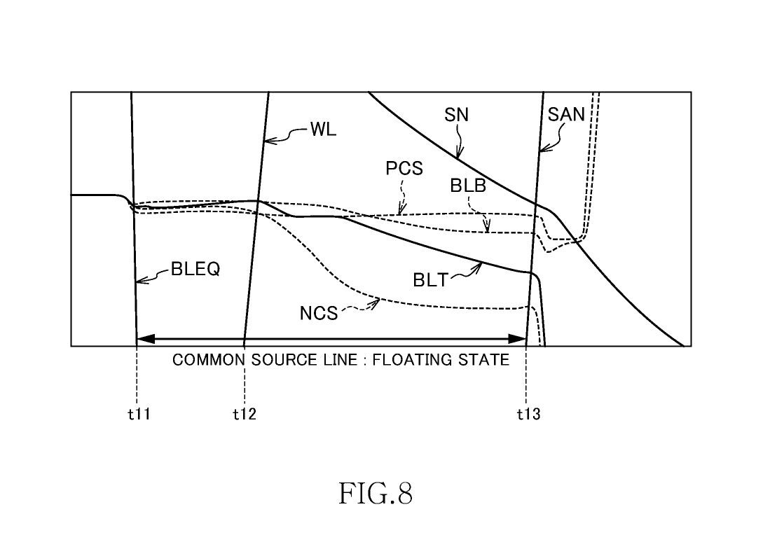

Turning to FIG. 8, in this example, the potential of the bit line BLT slightly increases in response to activation of a word line WL. However, because the potentials of the common source lines PCS and NCS are floating during a period from the time t12 to the time t13, the potential of the bit line BLT gradually decreases due to off-leakage current and becomes lower than the potential of the bit line BLB at a certain point of time. Accordingly, when the sense amplifier SA starts the sense operation upon activation of the timing signal SAN, inverse data is adversely output.

In the semiconductor device explained below, such an erroneous operation is prevented and an accurate sense operation can be performed.

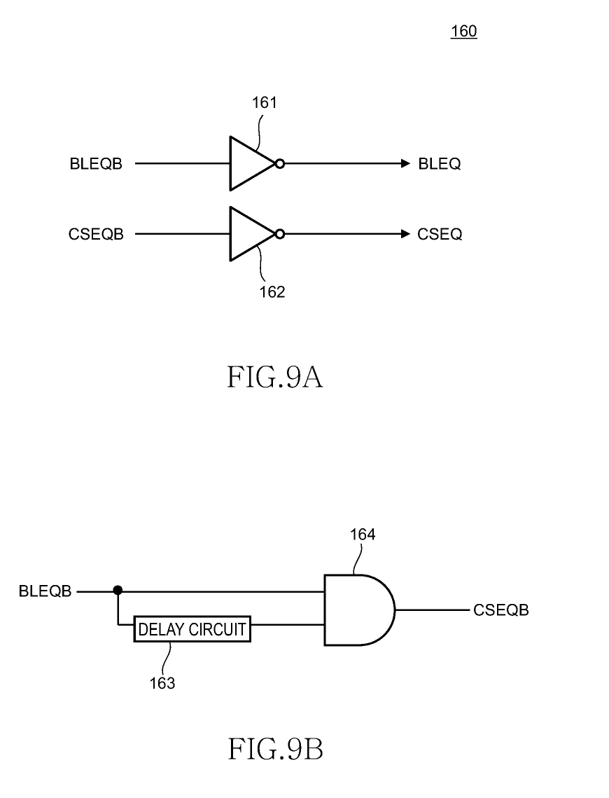

Turning to FIG. 9A, the equalization-signal generation circuit 160 includes an inverter circuit 161 that receives the bit-line equalization signal BLEQB, and an inverter circuit 162 that receives a common-source equalization signal CSEQB. An output of the inverter circuit 161 is used as the bit-line equalization signal BLEQ and an output of the inverter circuit 162 is used as the common-source equalization signal CSEQ. That is, in the first embodiment, a waveform of the bit-line equalization signal BLEQ and a waveform of the common-source equalization signal CSEQ can be separately controlled. Turning to FIG. 9B, the common-source equalization signal CSEQB can be generated based on the bit-line equalization signal BLEQB. In the example shown in FIG. 9B, the common-source equalization signal CSEQB is generated by a delay circuit 163 that delays the bit-line equalization signal BLEQB and an AND gate circuit 164 that receives the bit-line equalization signal BLEQB and an output signal from the delay circuit 163.

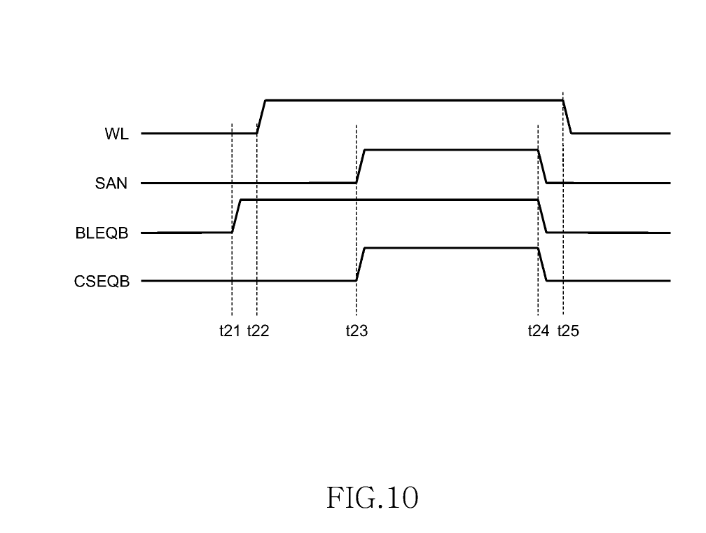

Turning to FIG. 10, the bit-line equalization signal BLEQB and the common-source equalization signal CSEQB are both activated to a low level in a period before a time t21. Accordingly, during this period, the bit-line precharge circuit BLPC and the common-source precharge circuit CSPC are both in an activated state and thus the bit line pair BLT and BLB and the common source lines PCS and NCS are all precharged with the precharge potential VBLP. The bit-line equalization signal BLEQB then changes to a high level at the time 21. This deactivates the bit-line precharge circuit BLPC and brings the bit line pair BLT and BLB into a floating state. However, because the common-source equalization signal CSEQB is kept at a low level, the precharge potential VBLP is continuously supplied to the common source lines PCS and NCS.

A predetermined word line WL is then activated to a high level at a time t22. This turns on the cell transistor Tr of the corresponding memory cell MC and connects the cell capacitor C thereof to the corresponding bit line BLT or BLB. As a result, the potential of the connected bit line BLT or BLB changes according to charges accumulated in the cell transistor Tr. This state is maintained for a while and, after the potential of the bit line BLT or BLB sufficiently changes, the timing signal SAN is activated to a high level and the common-source equalization signal CSEQB is deactivated to a high level at a time t23. Although not shown, the timing signal SAP1B is also activated to a low level at the time t23. Accordingly, the precharged states of the common source lines PCS and NCS are canceled and the sense amplifier SA is activated to amplify a potential difference occurring in the bit line pair BLT and BLB. As mentioned above, the timing signal SAP1B is activated only at the initial stage of the sense operation and the timing signal SAP2B is thereafter activated instead of the timing signal SAP1B to drive the common source line PCS to the array potential VARY.

At a time t24, the timing signal SAN is deactivated to a low level and the bit-line equalization signal BLEQB and the common-source equalization signal CSEQB are activated to a low level. When the word line WL is then deactivated to a low level at a time t25, restoring of data into the corresponding memory cell MC is completed.

With this control, because the precharge potential VBLP is continuously supplied to the common source lines PCS and NCS during a period after the word line WL is activated (the time t22) until the sense operation is started (the time t23), an erroneous operation resulting from the common source lines PCS and NCS brought into a floating state does not occur.

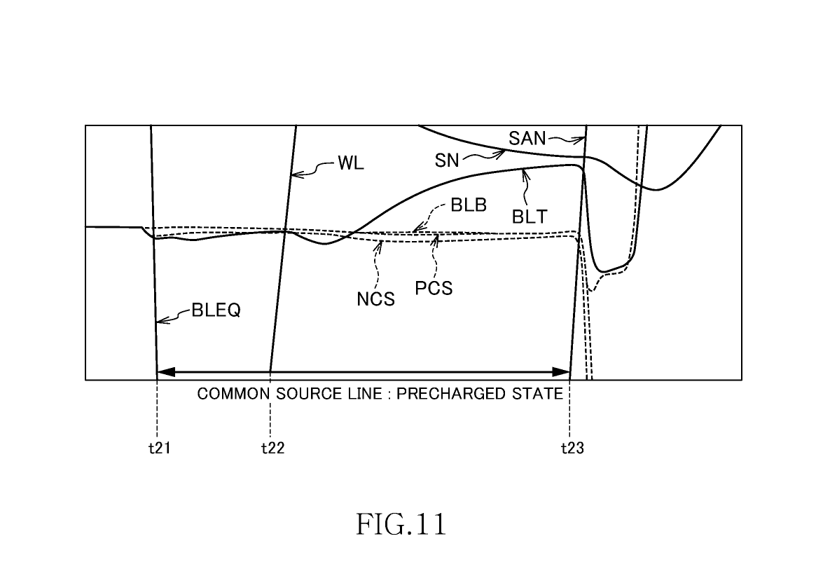

Turning to FIG. 11, in the first embodiment, while the potential of the bit line BLT slightly increases in response to activation of a word line WL, the common source lines PCS and NCS are fixed at the precharge potential VBLP and are hardly affected by off-leakage current during this period. Accordingly, a potential difference in the bit line pair BLT and BLB is accurately maintained and, when the sense amplifier SA starts the sense operation upon activation of the timing signal SAN, the sense operation can be accurately performed.

While the common-source equalization signal CSEQB is kept at a low level over the entire period from the time t22 to the time t23 in the first embodiment, this point is not essential to the present invention and it suffices to set the common-source equalization signal CSEQB to a low level during at least part of the period from the time t22 to the time t23. For example, the common-source equalization signal CSEQB can be set to a high level immediately before the time 23.

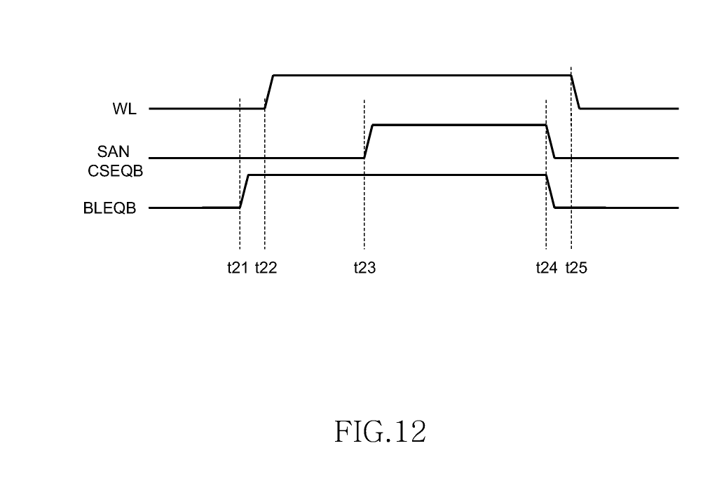

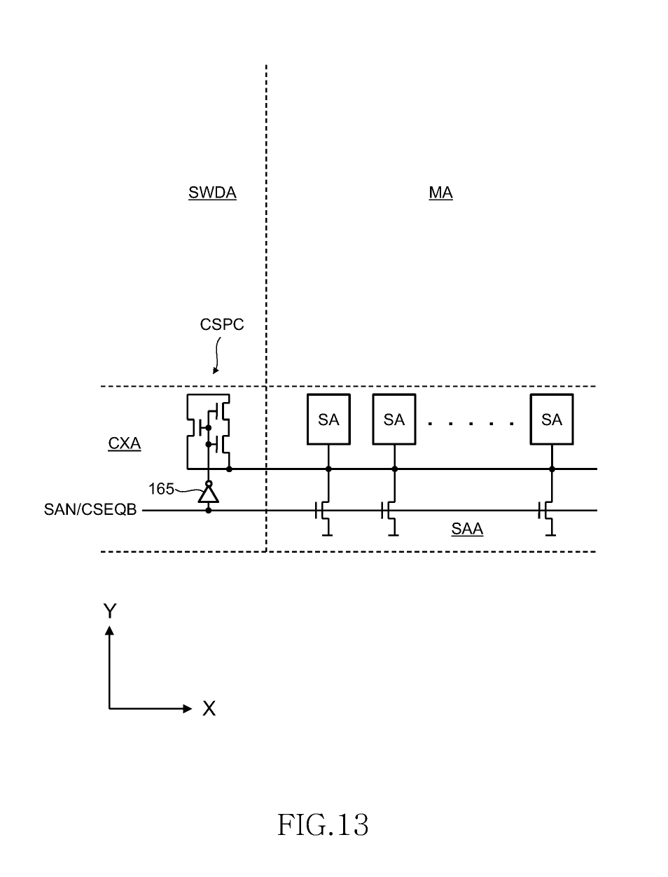

Turning to FIG. 12, in the second embodiment, the timing signal SAN is used also as the common-source equalization signal CSEQB. Because other features of the second embodiment are the same as those of the first embodiment, redundant explanations thereof will be omitted. The second embodiment eliminates the need to separately generate the common-source equalization signal CSEQB as well as achieving the effect according to the first embodiment. A line for transmitting the common-source equalization signal CSEQ is not required and a line for the timing signal SAN extending in an X direction on the sense amplifier area SAA can be branched into a cross area CXA, thereby controlling the common-source precharge circuit CSPC, as shown in FIG. 13. Besides the timing signal SAN, another signal for controlling the sense amplifier SA can be used also as the common-source equalization signal CSEQB or CSEQ.

Bit line equalization and common source equalization is described in U.S. Application publication No. 2010/0008129. The publication shows inverter 316 outputting BLEQ to transistors 231, 232 and 233 constituting the common source equalization circuit and transistors 321, 322 and 323 constituting the bit line equalization circuit in FIG. 2. The publication also shows X decoder/X timing generating circuit 802 to produce signals in FIG. 1 in response to address and control signals. The signals are applied to X control circuit 31 in FIG. 1. The disclosure of the above publication is incorporated herein in their entirety by reference thereto.

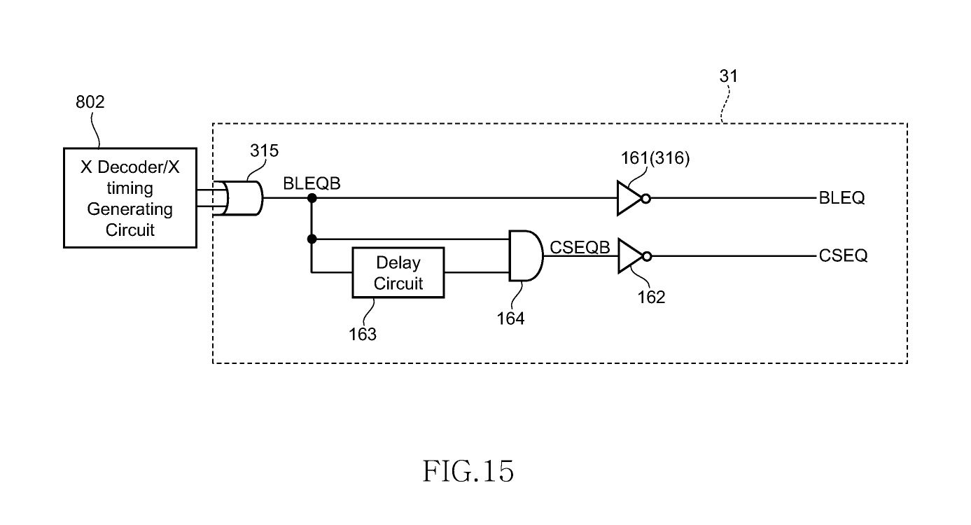

FIG. 15 illustrates a relationship between X decoder/X timing generating circuit 802 and circuits 160 shown in FIGS. 9A and 9B. It is noted that circuits 802, 315, 316, 318, 327 are shown by the incorporated reference. An OR circuit 315 outputs the BLEQB signal, which is inputted to the inverter 161 to produce the BLEQ signal. The BLEQB signal is used to produce the CSEQ signal via the delay circuit 163, the AND circuit 164 and the inverter 162. That is, the BLEQ signal is produced by allowing the BLEQB signal output from the logic circuit 315 to intervene a first logic circuit 161, and the CSEQ signal is produced by allowing the BLEQB signal output from the same logic circuit 315 to intervene a second logic circuit including the circuits 163, 164 and 162, which is different from the first logic circuit 161.

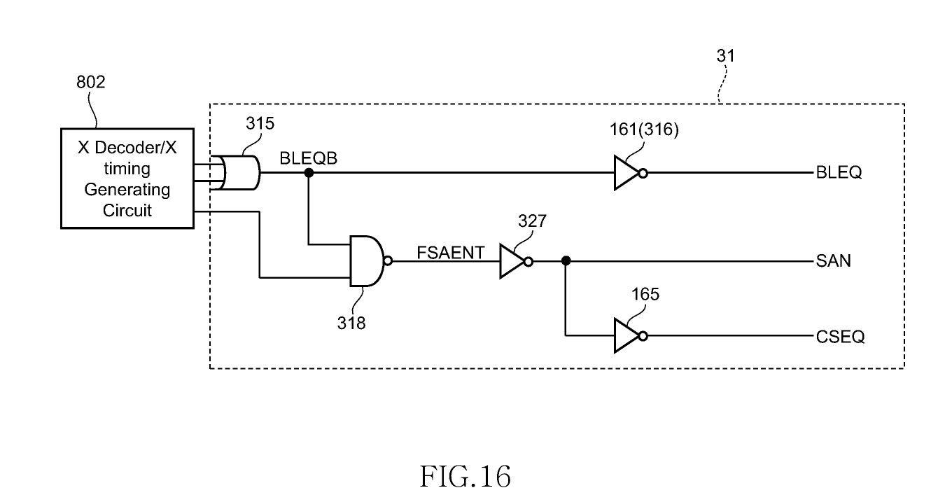

FIG. 16 illustrates a relationship between the X decoder/X timing generating circuit 802 and the circuits shown in FIG. 13 as the second embodiment. The CSEQ signal is produced by allowing the BLEQB signal output from the same logic circuit 315 to intervene a third logic circuit including NAND circuit 318, inverter 327 and the inverter 165. The third logic circuit is also different from the first logic circuit 161.

It is apparent that the present invention is not limited to the above embodiments, but may be modified and changed without departing from the scope and spirit of the invention.

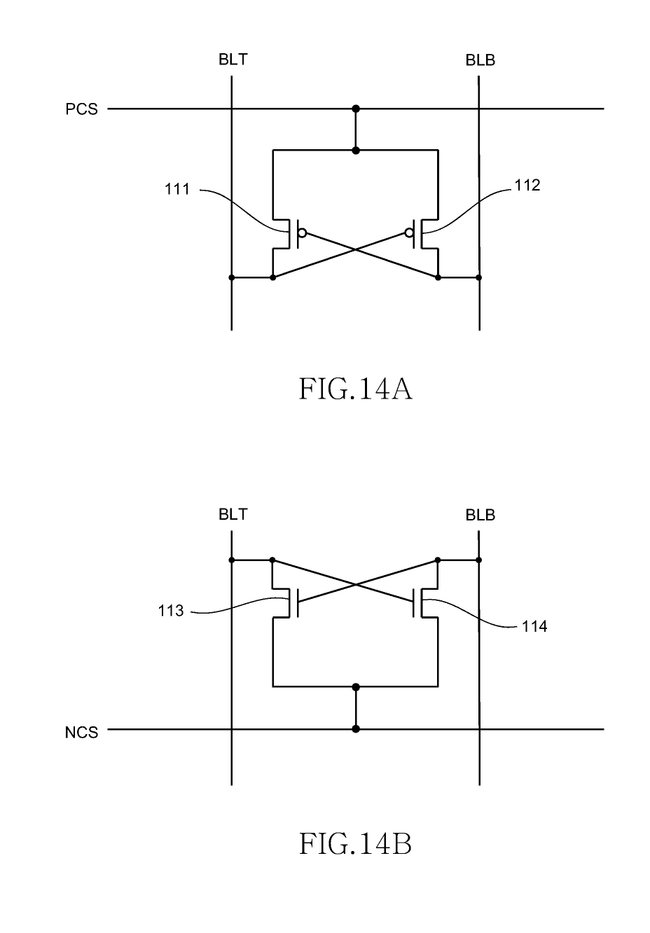

For example, while an example of using the sense amplifier SA including the four transistors 111 to 114 has been explained in the above embodiments, the sense amplifier in the present invention is not limited to the configuration. A sense amplifier including only the p-channel MOS transistors 111 and 112 as shown in FIG. 14A can be also used, or a sense amplifier including only the n-channel MOS transistors 113 and 114 as shown in FIG. 14B can be also used. Furthermore, it is not essential that the sense amplifier SA is constituted by MOS transistors and the sense amplifier SA can be constituted using other types of control elements such as bipolar transistors.

The embodiments described above have explained a case where the present invention is applied to a DRAM; however, the application target of the present invention is not limited to DRAMS. Therefore, it is possible to apply the present invention to other types of semiconductor memory devices such as an SRAM, a ReRAM, and a flash memory, and it is also possible to apply the present invention to logic semiconductor devices that have memory cell arrays incorporated in a part therein.

What is claimed is:

1. A semiconductor device comprising:
a first line;
a second line;
a first node;
a second node supplied with a first power supply potential;
a first control element that controls an amount of current flowing between the second line and the first node according to a potential of the first line;
a second control element that controls an amount of current flowing between the first line and the first node according to a potential of the second line;
a first control circuit that performs a first operation to fix potentials of the first and second lines at a first potential;
a second control circuit that performs a second operation to connect the first node to the second node; and
a third control circuit that fixes a potential of the first node at a second potential after the first control circuit stops the first operation until the second control circuit starts the second operation.

2. The semiconductor device as claimed in claim 1, wherein the first potential and the second potential are substantially the same potential.

3. The semiconductor device as claimed in claim 1, further comprising first and second memory cells,
wherein the first line receives data read from the first memory cell, and the second line receives data read from the second memory cell.

4. The semiconductor device as claimed in claim 1, wherein
the first control element comprises a first field-effect transistor having a gate electrode connected to the first line, a drain electrode connected to the second line, and a source electrode connected to the first node, and
the second control element comprises a second field-effect transistor having a gate electrode connected to the second line, a drain electrode connected to the first line, and a source electrode connected to the first node.

5. The semiconductor device as claimed in claim 4, wherein the first and second field-effect transistors are of an n-channel type, and the first power supply potential is a predetermined potential equal to or lower than a ground potential.

6. The semiconductor device as claimed in claim 4, wherein the first and second field-effect transistors are of a p-channel type, and the first power supply potential is a predetermined potential higher than a ground potential.

7. A semiconductor device comprising:
first and second bit lines;
a sense amplifier driving one of the first and second bit lines to a potential supplied to a first common source node, and driving the other of the first and second bit lines to a potential supplied to a second common source node;
a first precharge circuit that equalizes the first and second bit lines to substantially the same potential;
a second precharge circuit that equalizes the first and second common source nodes to substantially the same potential;
a first sense-amplifier drive circuit that drives the first common source node to a first activation potential; and
a second sense-amplifier drive circuit that drives the second common source node to a second activation potential, wherein
the first and second sense-amplifier drive circuits and the first and second precharge circuits are activated mutually exclusively, and
the second precharge circuit is deactivated after the first precharge circuit is deactivated.

8. The semiconductor device as claimed in claim 7, wherein the first precharge circuit precharges the first and second bit lines with a first potential.

9. The semiconductor device as claimed in claim 8, wherein the second precharge circuit precharges the first and second common source nodes with a second potential.

10. The semiconductor device as claimed in claim 9, wherein the first potential and the second potential are substantially the same potential.

11. The semiconductor device as claimed in claim 10, wherein the first and second potentials are an intermediate potential between the first activation potential and the second activation potential.

12. The semiconductor device as claimed in claim 7, wherein the first sense-amplifier drive circuit and the second precharge circuit are controlled by the same control signal.

13. A semiconductor device comprising:
first and second bit lines;
a first equalization circuit coupled to the first and second bit lines to equalize a potential between the first and second bit lines;
a sense amplifier coupled the first and second bit lines;
first and second source lines coupled to the sense amplifier to activate or deactivate the sense amplifier by a potential between the first and second source lines;
a second equalization circuit coupled to the first and second source lines to equalize the potential between the first and second source lines;
a first logic circuit configured to output a first control signal;
a second logic circuit configured to receive the first control signal and output a second control signal applied to the first equalization circuit; and
a third logic circuit configured to receive the first control signal and output a third control signal applied to the second equalization circuit, the third logic circuit being different from the second logic circuit.

14. The semiconductor device as claimed in claim 13, wherein the second equalization circuit maintains to equalize the potential between the first and second source lines after the first equalization circuit stops equalizing the potential between the first and second bit lines.

15. The semiconductor device as claimed in claim 14, wherein the second equalization circuit stops equalizing the potential between the first and second source lines when the sense amplifier is activated.
